(19) United States
(12) Patent Application Publication
(10) Pub. No.: US 2019/0148043 A1
(43) Pub. Date: May 16, 2019

(54) WIEGAND WIRE ARRANGEMENT AND METHOD FOR THE PRODUCTION THEREOF

(71) Applicants: Thomas Theil, Feldafing (DE); Walter Wehnert, Ottobrunn (DE)

(72) Inventors: Thomas Theil, Feldafing (DE); Walter Wehnert, Ottobrunn (DE)

(21) Appl. No.: 16/092,040

(22) PCT Filed: Apr. 8, 2016
(86) PCT No.: PCT/EP2016/000580

§ 371 Date: Jan. 10, 2019

(51) Int. Cl. H01F 1/147; G01D 5/20; H01F 27/28; H01F 41/06; H03K 3/45

(52) U.S. Cl. CPC H01F 1/147; G01D 5/2006; H01F 27/24; H01F 41/06; H03K 3/45; H01F 27/2823

(57) ABSTRACT

The invention relates to a Wiegand wire arrangement, with a Wiegand wire section, a winding device that defines an inner coil in which the Wiegand wire section is enclosed, and a coil carrier, which is designed as a tubular structure extending between the Wiegand wire section and the inner coil of the winding device inside the inner core, whereby the coil carrier is made of a metallic material.

### FIELD OF THE INVENTION

The invention relates to a Wiegand wire arrangement such as is used, for example, as an electrical voltage source for autonomous absolute sensors.

Wiegand wire arrangements that form an integral part of revolution counters are known from DE 102 59 223 B3 and EP 2 221 587 A2.

In a so-called Wiegand module, a coil is wound around the pulse or Wiegand wires (see also literature “Wiegand wire: New material for magnetic-based devices”, Electronics, Jul. 10, 1975), which delivers a voltage pulse when the wire is activated by an external magnetic field, which powers, for example, an electronic counting system. The tighter the coil is wound around the wire, the greater the magnetic coupling. Windings close to a pulse or Wiegand wire generate a greater EMF than those further from the wire. Furthermore, with an equal number of windings and an equal wire thickness, the internal resistance of the coil and the associated unavoidable losses are reduced. Nevertheless, it is not recommended to wind the coil directly onto the pulse or Wiegand wire, as this then poses the risk that the functioning of the wire, which is based on magnetostriction, is no longer guaranteed, or is at least impaired, as a result of the forces occurring.

### OBJECT OF THE INVENTION

The primary object of the invention is to produce a robust Wiegand wire arrangement that is advantageously feasible from a production point of view, whereby the inner coil is close to the pulse or Wiegand wire.

### Solution According to the Invention

According to a first aspect of the present invention, the above-mentioned object is achieved by means of a Wiegand wire arrangement, containing:
a Wiegand wire section,
a winding device that defines an inner coil in which the Wiegand wire section is enclosed, and
a coil carrier, which is designed as a tubular structure extending between the Wiegand wire section and the inner coil of the winding device inside the inner core, whereby
the coil carrier is made of a metallic material.

In this way, it is possible to produce a Wiegand wire arrangement in an advantageous manner, whereby the winding device can be attached to a inexpensively produced and mechanically resistant section of tube.

According to the invention, the coil carrier is produced as a non-magnetic or, if necessary, a sufficiently low-magnetic metallic tube and preferably coated with an electrically insulating oxide layer.

Furthermore, the coil carrier, which is designed as a small metallic tube, preferably has a surface roughness of less than 5 μm. In this way, it is possible to reliably prevent the thin insulation of the copper coil wire in the innermost winding layer of the coil from being punctured or contacted with little resistance.

Preferably, a sufficiently low-magnetic or non-magnetic metallic alloy is used as the material for the coil carrier, as the functioning of the Wiegand wire is based on the fact that its hard magnetic shell is not capable of switching the polarity of its soft magnetic core alone, but only with the help of an externally applied magnetic field (see also literature “Eigenschaften des Wiegand-Sensors”, messen+prüfen/automatik, May 1984). However, the sufficiently weak magnetic properties of the retaining and guiding element described here do not have a negative impact, provided that the functioning of the Wiegand wire is not impaired. This is the case, for example, with soft magnetic materials that have a permeability coefficient of less than 50. This means that the concept according to the invention can also be implemented for the retaining and guiding element using low-magnetic alloys (see also literature “Wissenswertes über Metall: Katalog der Firma Feldmann, Metall- und Schmiedekunst GmbH” or “Kleine Werkstoffkunde: Firma BNK-Stahl und Edelstahl, Material AISI 303”), i.e. those with a low coercive force and/or remanence above zero.

According to a particularly preferred embodiment of the invention, the coil carrier, i.e. the tube that surrounds the Wiegand wire section and holds the coil, is made of a nickel-titanium alloy. Such a thin tube advantageously proves to be extremely dimensionally stable. Besides its function as a guiding part for the pulse or Wiegand wire and as the carrier for the coil, it can also be connected to two separate plastic coil body parts. As explained below, this connection can be carried out by pressing in the tube (force-fitting). However, it can also be carried out by means of injection (form-fitting) or subsequent gluing. These two coil body parts both then serve as partition elements for the coil winding itself and also as carriers and fastening elements for the assembly and later connection of the module, e.g. on a circuit board. This provides particular advantages, especially in terms of cost-effective production, as relatively expensive self-bonding wire can be omitted and a normal enameled copper wire can be wound directly on the tube and secured and contacted with the coil body parts.

According to a further aspect of the present invention, the above-mentioned object according to the invention is also achieved by means of a method to produce a Wiegand module, in which a coil body, the innermost winding of which defines an inner coil in which a Wiegand wire section is enclosed, is formed in the course of a winding step. This winding step is carried out by winding a winding wire material, which is intended to form the coil body, onto a metallic tube to form the integral part of the Wiegand module. The metallic tube is preferably coated with an electrically insulating oxide layer in the course of a preparatory process step.

### BRIEF DESCRIPTION OF THE FIGURES

Further details and features of the invention are provided by the following description in conjunction with the drawing. The figures show the following:

FIG. 1 A schematic diagram to illustrate the structure of a Wiegand module according to the invention;

FIG. 2 An axial section view to illustrate the internal structure of the Wiegand module according to FIG. 1;

FIG. 3 A perspective view of another variant of a Wiegand module according to the invention.

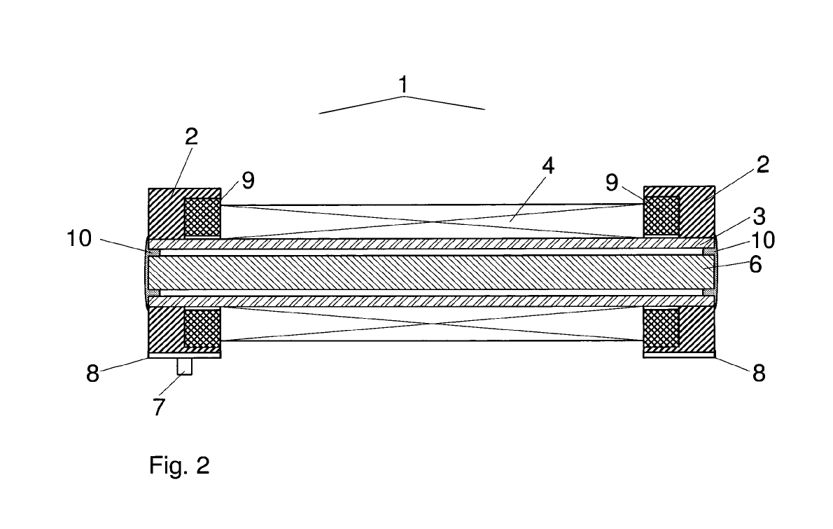

The drawings are not to scale and the supply lines to the coil are omitted in FIG. 2 for the sake of clarity. For the same reason, the gap between the pulse or Wiegand wire and the tube is shown greatly enlarged.

### DETAILED DESCRIPTION OF THE FIGURES

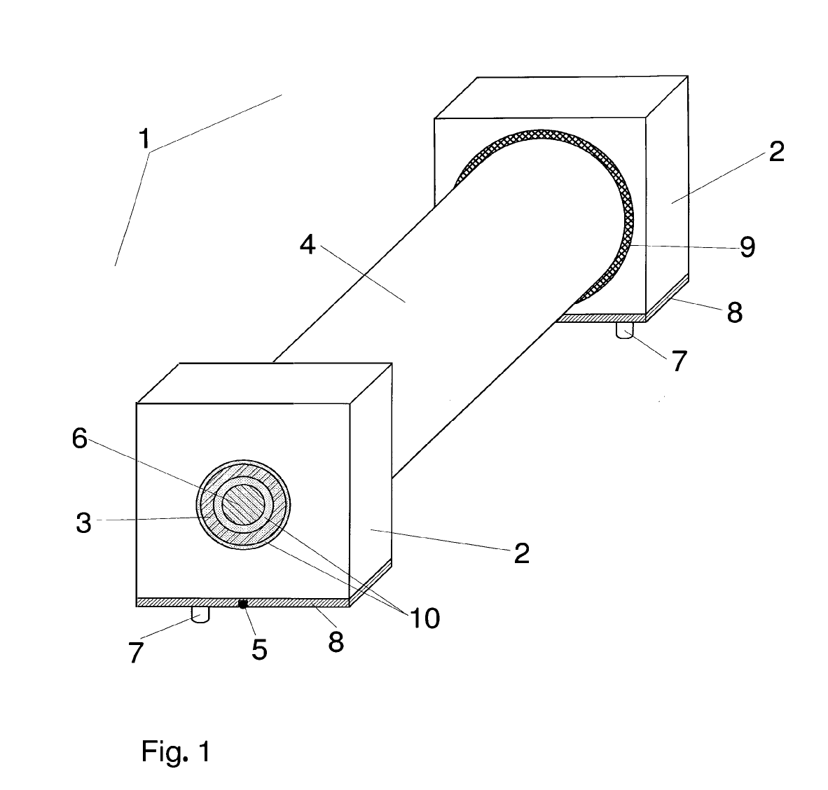

FIG. 1 illustrates the structure of a Wiegand module 1 according to the invention in the form of a perspective view. As shown in both FIGS. 1 and 2, the Wiegand module 1 has two, preferably identically designed, coil holder parts 2 made of plastic, which are joined by pressing in the tubular retaining and guiding element 3 to form a force-fit connection.

The wire ends 5 of the multi-layer enameled copper wire coil 4 that is wound directly onto the retaining and guiding element are each clamped into a slot on the underside of the coil holder parts 2, and the varnish is removed here to prepare for contacting on a circuit board. As an alternative to this clamping, other methods to fix the wire ends are also conceivable, e.g. ultrasonic welding. The corresponding surfaces 8 of the plastic elements 2 can, and should, also be suitably metalized for improved soldering on the circuit board. For more precise positioning of the whole module 1 on the circuit board, the coil holder parts 2 can be additionally fitted with suitable plastic tabs or pins 7.

Should it be necessary, for magnetic reasons, to magnetically stabilize the ends of the Wiegand or pulse wire using ferrite beads 9, these elements can be inserted or even injected into the plastic body. As a result of the flexible design of the plastic elements, many forms that are adapted to a specific application can generally be conceived, without affecting the inventive concept.

The pulse or Wiegand wire 6 is located inside the retaining and guiding element. Adhesive can be used to prevent it from falling out (e.g. with a drop of silicone adhesive 10 at each end, as shown). At the same time, the adhesive seals the inside of the tube to keep out dirt and liquids. A permanently flexible adhesive ensures, with sufficient reliability, that no forces that impair the functioning of the pulse or Wiegand wire can be exerted. However, if the expansion coefficient of the pulse or Wiegand wires is virtually identical to that of the metallic tubes, direct welding is also possible at one or even both of the ends.

Wherever this kind of Wiegand module is to be used, it provides a simple and inexpensive element for automatic assembly. The different variations, which may be necessary depending on the application, with differing numbers of windings, pulse or Wiegand wire lengths and forms of fastening element can be advantageously implemented on an application-specific basis by means of the simple and cost-saving adaptation of individual parts, such as the length or diameter of the tube.

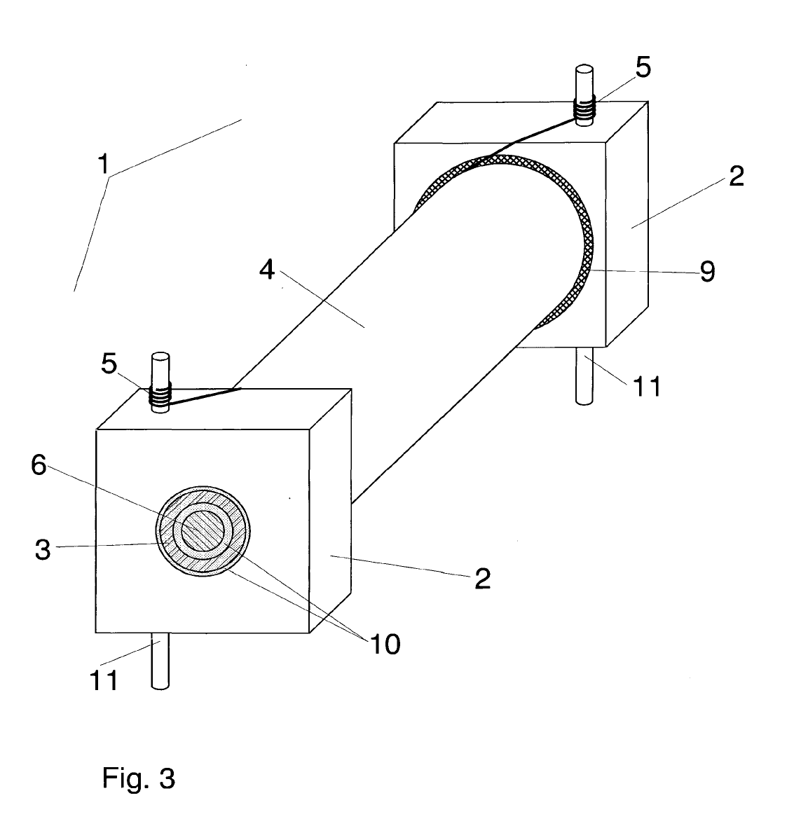

FIG. 3 depicts a third variant of a Wiegand module 1 according to the invention. The explanations of FIGS. 1 and 2 shall apply mutatis mutandis. The contact and positioning pin 11 is passed through the respective coil holder part 2 and this pin 11 is contacted with the respective wire end 5 on one of the sides of the coil holder part 2 facing away from the surface of the circuit board, as indicated.

### LIST OF REFERENCE NUMBERS

1. Complete module structure
2. Coil holder part
3. Retaining and guiding element
4. Enameled copper wire coil
5. Wire end of the enameled copper wire coil
6. Pulse or Wiegand wire
7. Tab or pin for positioning
8. Contact surface for soldering procedure
9. Ferrite bead
10. Adhesive (e.g. silicon)

1. Wiegand wire arrangement, comprising:
a Wiegand wire section;
a winding device, the inner winding of which defines an inner coil; and
a retaining and guiding element, which surrounds the Wiegand wire section and is enclosed in the inner coil, whereby the retaining and guiding element consists of a non-magnetic or sufficiently low-magnetic metal and encloses the Wiegand wire section in the form of a tube.

2. Wiegand wire arrangement according to claim 1, wherein the retaining and guiding element includes an inner wall coated with an electrically insulating oxide layer.

3. Wiegand wire arrangement according to claim 1, wherein the retaining and guiding element includes an outer wall coated with an electrically insulating oxide layer.

4. Wiegand wire arrangement according to claim 1, wherein the retaining and guiding element is formed of consists of a nickel-titanium alloy.

5. Wiegand wire arrangement of claim 4, wherein the alloy consists of 50% nickel and 50% titanium.

6. Wiegand wire arrangement of claim 1, wherein the retaining and guiding element has a surface roughness of below 5 μm.

7. Wiegand wire arrangement of claim 1, wherein the retaining and guiding element connects the coil body parts.

8. Wiegand wire arrangement according to claim 7, wherein the coil body parts are joined in a force-fitting manner.

9. Wiegand wire arrangement according to claim 7, wherein the coil body parts are joined in a form-fitting manner.

10. A method to produce a Wiegand module, in which a coil body, the innermost winding of which defines an inner coil in which a Wiegand wire section is enclosed, is formed in the course of a winding step wherein the winding step is carried out by winding a winding wire material, which is intended to form the coil body, onto a metallic tube to form the integral part of the Wiegand module.

11. The method claim 10, characterized in that the metallic tube is coated with an electrically insulating oxide layer in the course of a preceding process step.
